(19) United States
(12) Patent Application Publication
(10) Pub. No.: US 2012/0126312 A1
(43) Pub. Date: May 24, 2012

(54) VERTICAL DMOS-FIELD EFFECT TRANSISTOR

(75) Inventors: Gregory Dix, Tempe, AZ (US); Daniel Jackson, Phoenix, AZ (US)

(73) Assignee: Microchip Technology Incorporated

(21) Appl. No.: 13/288,181

(22) Filed: Nov. 3, 2011

Related U.S. Application Data
(60) Provisional application No. 61/415,449, filed on Nov. 19, 2010.

(51) Int. Cl. H01L 29/78; H01L 21/336

(52) U.S. Cl. 257/329; 438/268; 257/E29.262; 257/E21.41

(57) ABSTRACT

A vertical diffused metal oxide semiconductor (DMOS) field-effect transistors (FET), has a cell structure with a substrate; an epitaxial layer or well of the first conductivity type on the substrate; first and second base regions of the second conductivity type arranged within the epitaxial layer or well and spaced apart by a predefined distance; first and second source regions of a first conductivity type arranged within the first and second base region, respectively; a gate structure insulated from the epitaxial layer or well by an insulation layer and arranged above the region between the first and second base regions and covering at least partly the first and second base region, wherein the gate structure comprises first and second gates being spaced apart wherein each gate covers a respective portion of the base region.

### CROSS-REFERENCE TO RELATED APPLICATIONS

This application claims the benefit of U.S. Provisional Application No. 61/415,449 filed on Nov. 19, 2010, entitled “FORMING A LOW CAPACITANCE FIELD EFFECT TRANSISTOR BY REMOVAL OF A PORTION OF THE CONTROL GATE”, which is incorporated herein in its entirety.

### TECHNICAL FIELD

This application concerns a vertical DMOS-Field Effect Transistor (FET).

### BACKGROUND

Power metal oxide semiconductor field-effect transistors (MOSFET) are generally used to handle high power levels in comparison to lateral transistors in integrated circuits. FIG. 5 shows a typical MOSFET which uses a vertical diffused MOSFET structure, also called double-diffused MOSFET structure (DMOS or VDMOS).

As shown for example, in FIG. 5, on an N+ substrate 415 there is a N-epitaxial layer formed whose thickness and doping generally determines the voltage rating of the device. From the top into the epitaxial layer 410 there are formed N+ doped left and right source regions 430 surrounded by P-doped region 420 which forms the P-base surrounded by its out diffusion area 425. A source contact 460 generally contacts both regions 430 and 420 on the surface of the die and is generally formed by a metal layer that connects both left and right source region. An insulating layer 450, typically silicon dioxide or any other suitable material, insulates a polysilicon gate 440 which covers a part of the P-base region 420 and out diffusion area 425. The gate 440 is connected to a gate contact 470 which is usually formed by another metal layer. The bottom side of this vertical transistor has another metal layer 405 forming the drain contact 480. In summary, FIG. 5 shows a typical elementary cell of a MOSFET that can be very small and comprises a common drain, a common gate and two source regions and two channels. Other similar cells may be used in a vertical power MOS-FET. A plurality of such cells may generally be connected in parallel to form a power MOSFET.

In the On-state, a channel is formed within the area of regions 420 and 425 covered by the gate reaching from the surface into the regions 420 and 425, respectively. Thus, current can flow as indicated by the horizontal arrow. The cell structure must provide for a sufficient width d of gate 440 to allow for this current to turn into a vertical current flowing to the drain side as indicated by the vertical arrows.

Such structures have a relatively high gate to Drain capacitance due to the necessary width of the gate which is undesirable, in particular, in high frequency switching applications such as switched mode power supplies.

### SUMMARY

According to an embodiment, a vertical diffused metal oxide semiconductor (DMOS) field-effect transistors (FET), may have a cell structure comprising a substrate; an epitaxial layer or well of the first conductivity type on said substrate; first and second base regions of the second conductivity type arranged within said epitaxial layer or well and spaced apart by a predefined distance; first and second source regions of a first conductivity type arranged within said first and second base region, respectively; and a gate structure insulated from said epitaxial layer or well by an insulation layer and arranged above the region between the first and second base regions and covering at least partly said first and second base region, wherein the gate structure comprises first and second gates being spaced apart wherein each gate covers a respective portion of said base region.

According to a further embodiment, the base region may further comprise first and second diffusion areas of said second conductivity type surrounding said first and second base regions, respectively. According to a further embodiment, the vertical DMOS-FET may further comprise a source metal layer connecting said first and second source region and said first and second base region. According to a further embodiment, the vertical DMOS-FET may further comprise a gate metal layer connecting said first and second gate. According to a further embodiment, the first and second gate can be formed by a gate layer that connects the first and second gate. According to a further embodiment, the first and second gate can be connected outside the cell structure. According to a further embodiment, the first and second gate can be connected by wire bonding. According to a further embodiment, the vertical DMOS-FET may further comprise a drain metal layer on the backside of the substrate. According to a further embodiment, the cell structure or a plurality of cell structures can be formed in an integrated circuit device. According to a further embodiment, the integrated circuit device may provide for control functions for a switched mode power supply. According to a further embodiment, the first conductivity type can be P-type and the second conductivity type can be N-type. According to a further embodiment, the first conductivity type can be N-type and the second conductivity type can be P-type. According to a further embodiment, the substrate can be of the first or second conductivity type. According to a further embodiment, if said substrate is of the second conductivity type, the drain is connected through a top surface.

According to another embodiments, a method for manufacturing a cell structure of a vertical diffused metal oxide semiconductor (DMOS) field-effect transistors (FET), may comprise: forming a cell structure comprising first and second source regions of a first conductivity type for a vertical DMOS-FET in an epitaxial layer or well of a second conductivity type arranged on a substrate, wherein the first and second source regions are spaced apart by a predefined distance; forming an insulated gate layer on top of said epitaxial layer or well; patterning the gate layer to form first and second gates being spaced apart from each other.

According to a further embodiment of the method, the step of patterning can be performed in a single step. According to a further embodiment of the method, the step of patterning the gate layer may provide for a bridging area of the gate layer connecting the first and second gates. According to a further embodiment of the method, the bridging area can be located outside the cell structure. According to a further embodiment of the method, the method may further comprise connecting the first and second gates by a metal layer. According to a further embodiment of the method, the method may further comprise connecting the first and second gates by wire bonding. According to a further embodiment, the substrate can be of the first or second conductivity type. According to a further embodiment, if said substrate is of the second conductivity type, the drain is connected through a top surface.

### BRIEF DESCRIPTION OF THE DRAWINGS

FIG. 1 shows an embodiment of an improved vertical DMOS-FET.

FIG. 2A-2F shows several exemplary process steps for manufacturing a device as shown in FIG. 1.

FIG. 3 shows an exemplary partial top view of the device as shown in FIG. 1; and

FIGS. 4A and 4B show applications of the improved vertical DMOS-FET in single integrated chip.

FIG. 5 shows a conventional vertical DMOS-FET.

### DETAILED DESCRIPTION

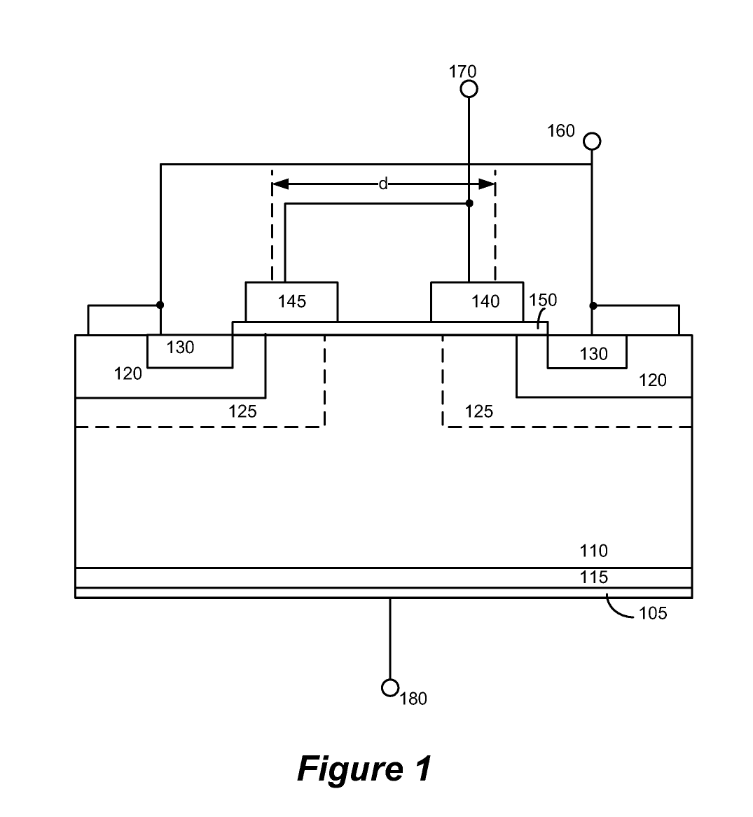

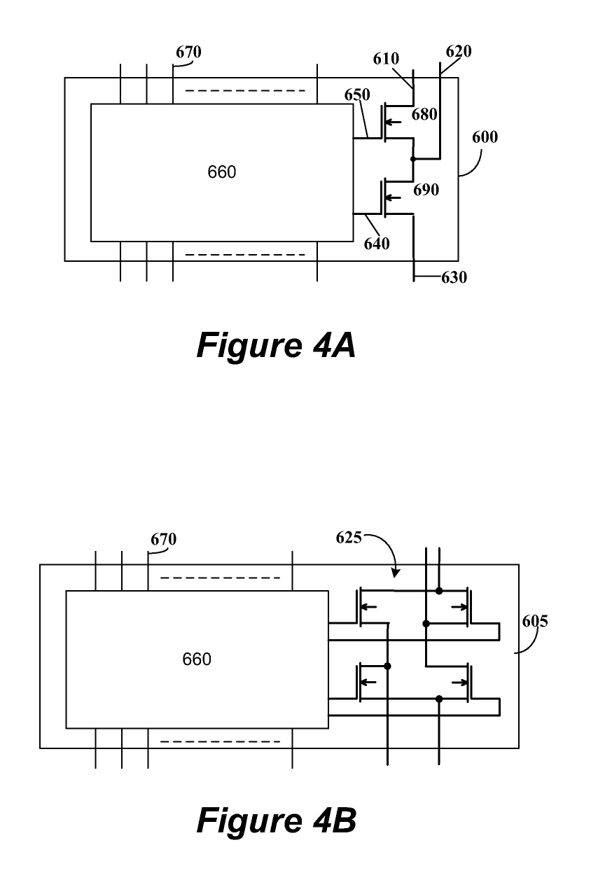

FIG. 1 shows a cross-sectional view of a vertical DMOS-FET according to various embodiments. Again, an N+ substrate 115 is provided on top of which an N-epitaxial layer 110 is formed. Alternatively, a N-well 110 can be formed on top of the substrate 115. The substrate can be either of N-type or of P-type as will be explained in more detail below. In the example shown in FIG. 1, layer 115 is an N+− substrate and from the top into the epitaxial layer 110 there are formed N+ doped left and right source regions 130 each surrounded by a P-doped region 120 which forms the P-base. Each P-base 120 is surrounded by an associated out diffusion area 125. Similar as for the transistor shown in FIG. 4, a source contact 160 generally contacts both regions 130 and 120 on the surface of the die and is generally formed by a metal layer that connects both left and right source region. Contrary to the conventional vertical DMOS-FET, an insulating layer 150 insulates separate left and right gates 140 and 145 each covering a part of the respective left and right P-base region 120 and associated out diffusion area 125. The gates are interconnected, for example by means of a metal or contact layer 170 or outside the gate effective area as will be explained in more detail below. Thus, according to various embodiments, the cell proposed structure does not only create two source regions 120, 125, 130 and two channels but also two gates 140 and 145. The gates can be formed by polysilicon, amorphous silicon or any other suitable conductive materials The bottom side of this vertical transistor has again another metal layer 105 forming the drain contact 180.

As mentioned above, according to various embodiments, the gates 140 and 145 do substantially not overlap such that two distinct gates are formed. Thus, the combined gate area for gates 140 and 145 when seen from atop is smaller than that of a conventional vertical transistor. Hence, the resulting individual gate-source and gate-drain capacitances are effectively are in sum smaller than the respective gate capacitances of a conventional vertical DMOS-FET as for example shown in FIG. 4. The various embodiments thus effectively take out the middle portion of the gate 440 of a conventional DMOS-FET thereby splitting the gate into two distinct gates 140 and 145. This can be done as much of the gate material is unnecessary for channel control. Thus, by removing the middle portion, the effective gate capacitance of this cell can be lowered without affecting the performance of the device. Depending on the manufacturing process, the split gate can be created by patterning of the gate layer in a single step. Hence, no additional masking steps are required. The middle section of gate 440 that is to be taken out may be very small, however, available lithography techniques will be capable of resolving the spaces involved and thus allow to create such a structure.

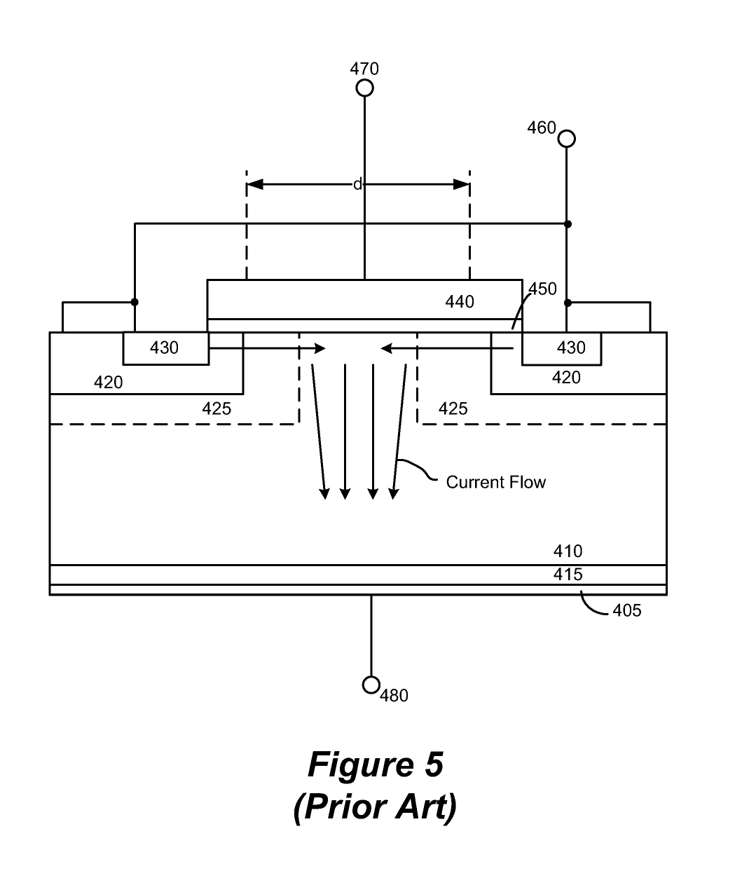

Alternatively, as mentioned above different types of substrate 110 can be used. For example, the substrate 110 can be a N+, a N++, or an N substrate, or can even be a P-type substrate. Thus, layer 110 can be an epitaxial layer or just a diffused N-type well. In case the substrate is N-doped, and a N-type well 110 is formed, the same structure as mentioned above with respect to the N-epitaxial layer will be formed. In case the substrate is P-doped, while the remaining structure and conductivity types remain as mentioned above, the substrate could not be used as the drain anymore. In this case, the drain would be connected through the top surface instead of the substrate layer. However, the device would still be considered to be a vertical transistor because current would generally flow vertically as indicated in FIG. 5 but would then also move laterally through the N-well and be collected on the top side.

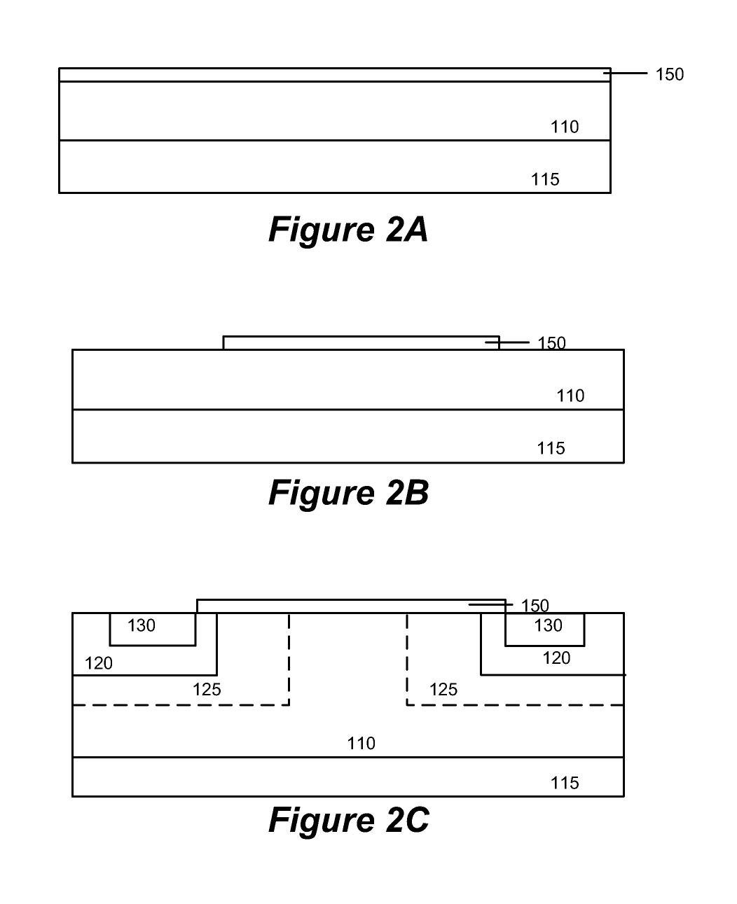

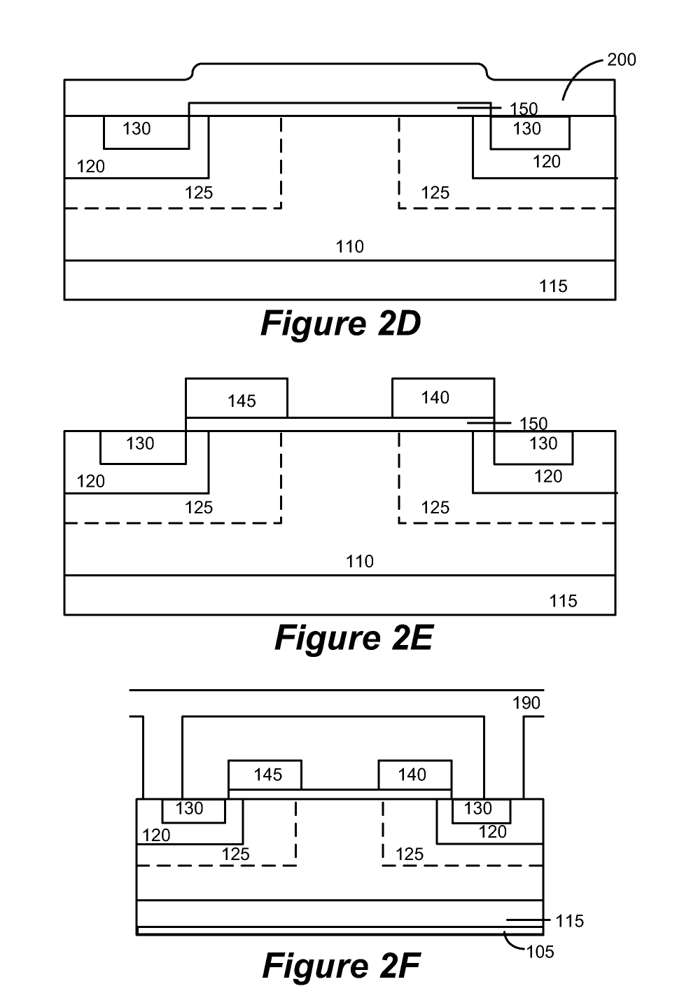

FIG. 2A-2F show exemplary process steps for manufacturing a device as shown in FIG. 1. However, according to the applied technology other steps may be suitable to produce a similar device. As shown in FIG. 2A, an N-doped epitaxial layer 110 is grown on an N+ substrate 115. On top of the epitaxial layer 110 an oxide layer 150 is deposited. the oxide layer 150 can be patterned as shown in FIGS. 2B and N+-doped source regions 130 and surrounding base regions 120 with associated out diffusion areas 125 can be created with well known diffusion techniques as shown in FIG. 2C. FIG. 2D shows the die with a polysilicon layer 200 which is deposited on top of the die. As mentioned above, amorphous silicon or any other suitable gate material can be deposited as the gate layer 200. The gate layer 200 can then be patterned using known masking techniques to form gates 140 and 145 as shown in FIG. 2E. FIG. 2F shows the cell structure with an additional metal layer 190 connecting the left and right source regions 130 and associated P-base regions 120. Furthermore, FIG. 2F shows the back metal layer 105 contacting the drain region 115.

The step of patterning the gate layer 200 can be performed in one single step. Thus, no additional process step is required. However, according to other embodiments, more than one step may be used. For example, if the gate as shown in FIG. 4 is used as a mask to form the source regions then splitting the gates into two separate gates may be performed by another step.

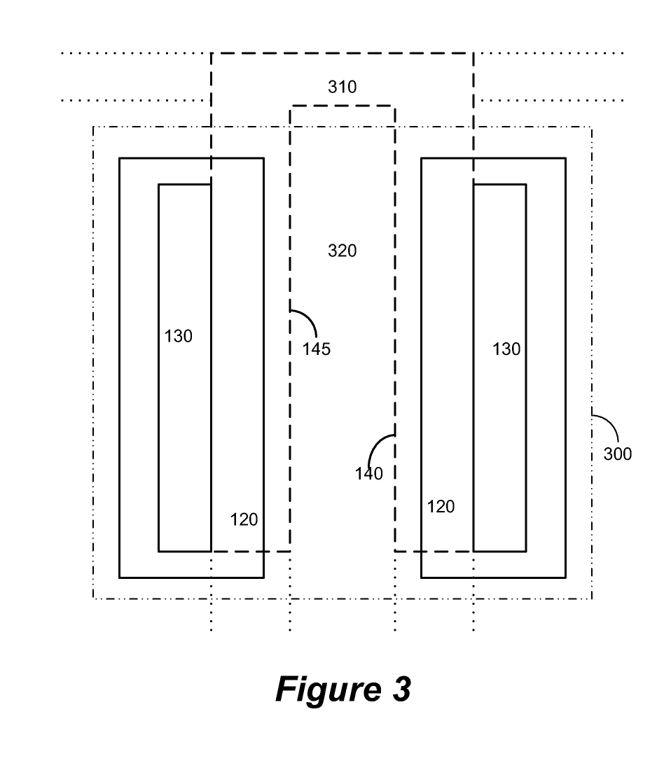

FIG. 3 shows a top view of a cell 300 according to FIG. 1 wherein only certain areas of the cell are highlighted. As can be seen, the left and right source regions 130 are surrounded by the P-base region 120. The broken lines indicate the position of the overlaid gates 140 and 145. Mid section 300 of the gate layer is removed to form individual left gate 145 and right gate 140. The gate layer 200 may be patterned to completely separate left and right gate by removing the inner section 320 and a metal layer may be used to connect the individual gate portions on the chip. According to other embodiments, well known bonding techniques may be used to connect the gates, for example outside the chip by means of a leadframe. However, the gate layer 200 can also be patterned as shown in FIG. 3 such that a bridging area 310 is formed outside the cell area. However, according to other embodiments, the bridging area 310 may reach into the cell and cover an insubstantial part of the cell without influencing the gate capacitance significantly. The gate layer 200 may be furthermore patterned to connect a plurality of gates from neighboring cells as indicated by the dotted lines on the left and right and bottom sides of the gate structure shown in FIG. 3.

The cell structure can be a stripe structure as shown in FIG. 3. However, according to other embodiments may use square cells, hexagonal shapes or any other suitable cell shape for which the principle of the various embodiments can be applied to. The cell structure or a plurality of cells can be used to form a power DMOS-FET within an integrated circuit or in a discrete transistor device. Such an integrated circuit may provide control circuits for use in a switched mode power supply. Thus, no external power transistors may be necessary.

FIG. 4A shows schematically how a microcontroller 660 can be combined with two power transistors 680 and 690 according to various embodiments as shown in FIGS. 1-3 on a single chip 600. Alternatively, the microcontroller 660 and the transistors 680, 690 may be provided on separate chips within a single housing. Microcontroller 660 may have a plurality of peripheral devices such as controllable drivers, modulators, in particular pulse width modulators, timers etc. and is capable to drive the gates 640 and 650 of transistors 680 and 690 directly or through respective additional drivers. The chip 600 can be configured to make a plurality of functions of the microcontroller available through external connections or pins 670. The source of first transistor 680 can be connected to external connection or pin 610. Similarly, external connection 620 provides a connection to the combined drain and source of transistors 680 and 690 and external connection or pin 630 for the drain of the second transistor 630. Other transistor structures manufactured in accordance with the various embodiments disclosed can be used, such as an H-bridge or multiple single transistors. FIG. 4B shows an exemplary plurality of MOSFETs connected to form an H-Bridge 625 that can be coupled with a microcontroller 660 or modulator within a single semiconductor chip 605.

Furthermore, the exemplary embodiment shows a N-channel device with appropriate conductivity types of the different regions. A person skilled in the art will appreciate that the embodiments of the present application are not restricted to N-channel devices but can be also applied to P-Channel devices.

What is claimed is:

1. A vertical diffused metal oxide semiconductor (DMOS) field-effect transistors (FET), with a cell structure comprising:
a substrate;
an epitaxial layer or well of a first conductivity type on said substrate;
first and second base regions of the second conductivity type arranged within said epitaxial layer or well and spaced apart by a predefined distance;
first and second source regions of a first conductivity type arranged within said first and second base region, respectively;
a gate structure insulated from said epitaxial layer or well by an insulation layer and arranged above the region between the first and second base regions and covering at least partly said first and second base region, wherein the gate structure comprises first and second gates being spaced apart wherein each gate covers a respective portion of said base region.

2. The vertical DMOS-FET according to claim 1, wherein the base region further comprising first and second diffusion areas of said second conductivity type surrounding said first and second base regions, respectively.

3. The vertical DMOS-FET according to claim 1, further comprising a source metal layer connecting said first and second source region and said first and second base region.

4. The vertical DMOS-FET according to claim 1, further comprising a gate metal layer connecting said first and second gate.

5. The vertical DMOS-FET according to claim 1, wherein the first and second gate are formed by a gate layer that connects the first and second gate.

6. The vertical DMOS-FET according to claim 5, wherein the first and second gate are connected outside the cell structure.

7. The vertical DMOS-FET according to claim 1, wherein the first and second gate are connected by wire bonding.

8. The vertical DMOS-FET according to claim 1, further comprising a drain metal layer on the backside of the substrate.

9. The vertical DMOS-FET according to claim 1, wherein the cell structure or a plurality of cell structures are formed in an integrated circuit device.

10. The vertical DMOS-FET according to claim 9, wherein the integrated circuit device provides for control functions for a switched mode power supply.

11. The vertical DMOS-FET according to claim 1, wherein the first conductivity type is P-type and the second conductivity type is N-type.

12. The vertical DMOS-FET according to claim 1, wherein the first conductivity type is N-type and the second conductivity type is P-type.

13. The vertical DMOS-FET according to claim 1, wherein the substrate is of the first or second conductivity type.

14. The vertical DMOS-FET according to claim 13, wherein if said substrate is of the second conductivity type, the drain is connected through a top surface.

15. A method for manufacturing a cell structure of a vertical diffused metal oxide semiconductor (DMOS) field-effect transistors (FET), comprising:
forming a cell structure comprising first and second source regions of a first conductivity type for a vertical DMOS-FET in an epitaxial layer or well of a second conductivity type arranged on a substrate, wherein the first and second source regions are spaced apart by a predefined distance;
forming an insulated gate layer on top of said epitaxial layer or well;
patterning the gate layer to form first and second gates being spaced apart from each other.

16. The method according to claim 15, wherein the step of patterning is performed in a single step.

17. The method according to claim 15, wherein the step of patterning the gate layer provides for a bridging area of the gate layer connecting the first and second gates.

18. The method according to claim 17, wherein the bridging area is located outside the cell structure.

19. The method according to claim 15, further comprising connecting the first and second gates by a metal layer.

20. The method according to claim 15, further comprising connecting the first and second gates by wire bonding.

21. The method according to claim 15, wherein the substrate is of the first or second conductivity type.

22. The method according to claim 15, wherein if said substrate is of the second conductivity type, the drain is connected through a top surface.
